(19) United States
(12) Patent Application Publication
(10) Pub. No.: US 2026/0248053 A1
(43) Pub. Date: Aug. 20, 2026

(54) PACKAGE STRUCTURE AND PACKAGE METHOD

(71) Applicant: JCET Microelectronics (Jiangyin) Co., LTD., Jiangyin (CN)

(72) Inventors: Haijie CHEN, Jiangyin (CN); Jingyu WU, Jiangyin (CN)

(73) Assignee: JCET Microelectronics (Jiangyin) Co., LTD., Jiangyin (CN)

(21) Appl. No.: 19/537,193

(22) Filed: Feb. 11, 2026

(30) Foreign Application Priority Data
Feb. 18, 2025 (CN) 202510179480.0

(51) Int. Cl. H10W 90/00; H10W 74/10

(52) U.S. Cl. CPC H10W 90/722; H10W 74/117; H10W 90/724

(57) ABSTRACT

A package structure and a package method are provided. The package structure includes: a first carrier board including a first line; a first chip structure including: a first functional layer located on the first carrier board and a second functional layer bonded on the first functional layer, and one of the first functional layer and the second functional layer is a power layer and the other is a signal layer; and a first interconnection structure located on the first carrier board at a side of the first chip structure and on a top of the second functional layer facing away from the first functional layer, respectively. The first interconnection structure at the side of the first chip structure is connected to the first functional layer through the first line, and the first interconnection structure on the top of the second functional layer is connected to the second functional layer.

### CROSS-REFERENCE TO RELATED APPLICATIONS

This application claims the benefit of priority to Chinese Application No. 202510179480.0, filed on February 18, 2025, which is incorporated herein by reference in its entirety.

### TECHNICAL FIELD

The present disclosure relates to the field of package technology, particularly relates to a package structure and a package method.

### BACKGROUND

With the continuous evolution of semiconductor technology, in order to improve logic density and efficiency, the architecture and circuit design of chips will also undergo significant adjustments, and advanced package technology will gradually become one of the key factors driving chip performance improvement.

### SUMMARY

The embodiments of the present disclosure is to provide a package structure and a package method.

The embodiments of the present disclosure provide a package structure, which includes: a first carrier board, the first carrier board has a first line; a first chip structure including a first functional layer located on the first carrier board and a second functional layer bonded on the first functional layer, the first functional layer is electrically connected with the first carrier board, and the second functional layer is electrically connected with the first functional layer, and one of the first functional layer and the second functional layer is a power layer and the other is a signal layer; and a first interconnection structure located on the first carrier board at the side of the first chip structure and on the top of the second functional layer facing away from the first functional layer, respectively, and the first interconnection structure at the side of the first chip structure is electrically connected with the first functional layer through the first line, and the first interconnection structure on the top of the second functional layer is electrically connected with the second functional layer.

Correspondingly, the embodiments of the present disclosure also provide a package method, which includes: providing a first carrier board, the first carrier board has a first line; arranging a first chip structure on the first carrier board, the first chip structure includes a first functional layer located on the first carrier board and a second functional layer bonded on the first functional layer, and the first functional layer is electrically connected with the first carrier board, and the second functional layer is electrically connected with the first functional layer, and one of the first functional layer and the second functional layer is a power layer and the other is a signal layer; and forming a first interconnection structure on the first carrier board at the side of the first chip structure and on the top of the second functional layer facing away from the first functional layer, respectively, and the first interconnection structure at the side of the first chip structure is electrically connected with the first functional layer through the first line, and the first interconnection structure on the top of the second functional layer is electrically connected with the second functional layer.

The embodiments of the present disclosure provide a package structure, which includes: a first carrier board having a first line; a first chip structure including a first functional layer located on the first carrier board and a second functional layer bonded on the first functional layer, and the first functional layer is electrically connected with the first carrier board, and the second functional layer is electrically connected with the first functional layer, and one of the first functional layer and the second functional layer is a power layer and the other is a signal layer; and a first interconnection structure located on the first carrier board at the side of the first chip structure and on the top of the second functional layer facing away from the first functional layer, respectively, and the first interconnection structure at the side of the first chip structure is electrically connected with the first functional layer through the first line, and the first interconnection structure on the top of the second functional layer is electrically connected with the second functional layer; in the present embodiments, the power layer and the signal layer in the first chip structure are arranged stacked on the top of one another, which is conductive to improving the integration degree of the first chip structure and reducing the space occupied by the first chip structure in the package structure; furthermore, the first interconnection structure at the side of the first chip structure is electrically connected with the first functional layer through the first carrier board, and the first interconnection structure on the top of the second functional layer is electrically connected with the second functional layer.

The embodiments of the present disclosure further provide a package method: a first chip structure is arranged on a first carrier board having a first line, and the first chip structure includes a first functional layer located on the first carrier board and a second functional layer bonded on the first functional layer, and the first functional layer is electrically connected with the first carrier board, and the second functional layer is electrically connected with the first functional layer, and one of the first functional layer and the second functional layer is a power layer and the other is a signal layer; and a first interconnection structure is formed on the first carrier board at the side of the first chip structure and on the top of the second functional layer facing away from the first functional layer, respectively, and the first interconnection structure at the side of the first chip structure is electrically connected with the first functional layer through the first line, and the first interconnection structure on the top of the second functional layer is electrically connected with the second functional layer; in the present embodiments, the power layer and the signal layer in the first chip structure are arranged stacked on the top of one another.

### BRIEF DESCRIPTION OF THE DRAWINGS

FIG. 1 is a structural schematic diagram of a first embodiment of the package structure of the present disclosure;

FIG. 2 is a structural schematic diagram of a second embodiment of the package structure of the present disclosure;

FIGS. 3 to 9 are structural schematic diagrams corresponding to each step in a first embodiment of the package method of the present disclosure; and

FIG. 10 is a structural schematic diagram corresponding to some steps in a second embodiment of the package method of the present disclosure.

### DETAILED DESCRIPTION

In related field of advanced packages, the power layer and signal layer are typically located on the same side of the substrate, i.e., the signal transmission circuit of the signal layer and the power supply circuit of the power layer coexist on the front surface of the chip, and the signal transmission circuit and the power supply circuit share the space on the front surface of the chip.

However, as the complexity degree and requirements for integration degree of package structure keep rising, the interference of power supply circuits on signals in the signal layer is receiving more and more attention, and this interference will lead to logic errors and ultimately may increase the overall voltage and power consumption of the package structure.

In chip manufacturing and advanced package, signal transmission circuit of the signal layer and power supply circuit of the power layer typically coexist on the front surface of the chip, and the signal transmission circuit and the power supply circuit share the space on the front surface of the chip, which makes it difficult to further reduce the volume of the package structure; furthermore, since the signal transmission circuit and the power supply circuit are both located on the front surface of the chip, correspondingly, the power supply circuit interferes with signals in the signal layer, so that the overall voltage and power consumption of the package structure are increased.

In order to solve the aforementioned technical problem, the package structure provided by the embodiments of the present disclosure includes: a first carrier board, the first carrier board has a first line; a first chip structure including a first functional layer located on the first carrier board and a second functional layer bonded on the first functional layer, and the first functional layer is electrically connected with the first carrier board, and the second functional layer is electrically connected with the first functional layer, and one of the first functional layer and the second functional layer is a power layer and the other is a signal layer; and a first interconnection structure which is respectively located on the first carrier board at the side of the first chip structure and on the top of the second functional layer facing away from the first functional layer, and the first interconnection structure at the side of the first chip structure is electrically connected with the first functional layer through the first line, and the first interconnection structure on the top of the second functional layer is electrically connected with the second functional layer.

In the solution disclosed by the present disclosure, the power layer and the signal layer in the first chip structure are arranged stacked on the top of one another, which is conductive to improving the integration degree of the first chip structure and reducing the space occupied by the first chip structure in the package structure; furthermore, the first interconnection structure at the side of the first chip structure is electrically connected with the first functional layer through the first carrier board, and the first interconnection structure on the top of the second functional layer is electrically connected with the second functional layer, consequently, the power supply circuit of the power layer can be separated from the signal transmission circuit of the signal layer, and the interference of the power supply circuit of the power layer on signals in the signal layer is effectively reduced, so that the overall voltage and power consumption of the package structure are reduced and the efficiency of the package structure is improved.

To make the objects, features, and advantages of the embodiments of the present disclosure more apparent and understandable, specific embodiments of the present disclosure are described in detail below in conjunction with the accompanying drawings.

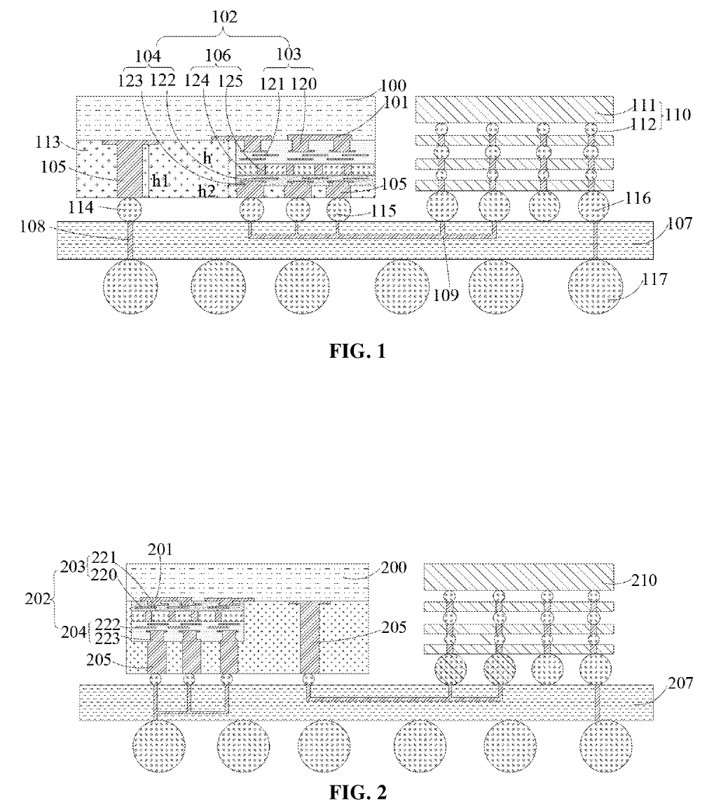

FIG. 1 is a structural schematic diagram of a first embodiment of the package structure of the present disclosure.

Referring to FIG. 1, the package structure includes: a first carrier board 100, the first carrier board 100 has a first line 101; a first chip structure 102 including a first functional layer 103 located on the first carrier board 100 and a second functional layer 104 bonded on the first functional layer 103, and the first functional layer 103 is electrically connected with the first carrier board 100, and the second functional layer 104 is electrically connected with the first functional layer 103, and one of the first functional layer 103 and the second functional layer 104 is a power layer and the other is a signal layer; and a first interconnection structure 105 located on the first carrier board 100 at the side of the first chip structure 102 and on the top of the second functional layer 104 facing away from the first functional layer 103, respectively, and the first interconnection structure 105 at the side of the first chip structure 102 is electrically connected with the first functional layer 103 through the first line 101, and the first interconnection structure 105 on the top of the second functional layer 104 is electrically connected with the second functional layer 104.

The first carrier board 100 is used as a package carrier to provide support for the first chip structure 102 and to provide electrical connection paths with other circuits for the first chip structure 102, thereby achieving the package integration and electrical integration of the first chip structure 102.

As an example, the first carrier board 100 is a silicon carrier board. In other embodiments, the first carrier board may also be other types of carrier boards with first lines, for example, the first carrier board may also be a glass carrier board, a resin substrate, a ceramic substrate, or a printed circuit board (PCB), etc.

In the present embodiment, the first line 101 is a redistribution layer (RDL) used to electrically connect the first functional layer 103 and the first interconnection structure 105 on the first carrier board 100. In other embodiments, the first line may also be other types of wiring structures, for example, the first line may include an interconnection layer and interconnection through-hole structures electrically connected with the interconnection layer.

In the present embodiment, the first chip structure 102 is a logic chip structure with a specific function. In some embodiments, the type of first chip structure 102 is determined according to actual functional requirements or application scenarios, for example, the first chip structure 102 includes gate arrays, unit substrate arrays, embedded arrays, structured application specific integrated circuits (ASICs), field programmable gate arrays (FPGAs), complex programmable logic devices (CPLDs), central processing units (CPUs), processing units (XPUs), microprocessing units (MPUs), microcontroller units (MCUs), logic integrated circuits (ICs), application processors (APs), display driver ICs (DDIs), radio frequency (RF) chips, power chips, or complementary metal oxide semiconductor (CMOS) image sensors.

One of the first functional layer 103 and the second functional layer 104 serves as a power layer, and the other serves as a signal layer.

In the present embodiment, the first functional layer 103 is the power layer, and the second functional layer 104 is the signal layer, correspondingly, when the first chip structure 102 is subsequently bonded on the second carrier board, which facilitates electrical connection between the signal layer and other chip structures through the second carrier board, meanwhile, the transmission path between the signal layer and the second carrier board is also shortened, and interference between lines is reduced.

In some embodiments, an external voltage supplies power to the signal layer through the power layer (i.e., the first functional layer 103), and the signal layer (i.e., the second functional layer 104) is used to achieve signal transmission between different chip structures.

It should be noted that the first functional layer 103 includes a first conductive layer 121 and a first lead 120 electrically connected with the first conductive layer 121, and the first lead 120 is located at a side of the first functional layer 103 facing the first carrier board 100, and another end of the first lead 120 is electrically connected with the first line 101; the second functional layer 104 includes a second conductive layer 122 and a second lead 123 electrically connected with the second conductive layer 122, and the second lead 123 is located at a side of the second functional layer 104 facing away from the first carrier board 100, and another end of the second lead 123 is electrically connected with the first interconnection structure 105 on the top of the second functional layer 104.

In the present embodiment, the second functional layer 104 is bonded on the first functional layer 103, i.e., the first functional layer 103 and the second functional layer 104 can be fabricated respectively, so that process compatibility between the two can be improved, meanwhile, the process flow can be simplified, and process complexity is reduced, and the yield of the package structure is improved.

In the present embodiment, the first chip structure 102 further includes: a bonding layer 106 located between the first functional layer 103 and the second functional layer 104, and the bonding layer 106 has in it a second interconnection structure 125, and the second interconnection structure 125 is electrically connected with the first functional layer 103 and the second functional layer 104.

In some embodiments, the bonding layer 106 is a hybrid bonding layer, and the bonding layer 106 includes an insulating layer 124 and the second interconnection structure 125 located within the insulating layer 124, and the first functional layer 103 and the second functional layer 104 are electrically connected through the second interconnection structure 125.

It should be noted that, the fact that the bonding layer 106 is a hybrid bonding layer facilitates increasing the number of second interconnection structures 125, and also facilitates reducing the thickness of the package structure.

As an example, the second interconnection structure 125 may be conductive pillars passing through the insulating layer 124.

In other embodiments, according to actual process requirements, the second interconnection structure may also include an interconnection layer and interconnection through-hole structures electrically connected with the interconnection layer. In other embodiments, the bonding layer may also be composed of conductive bumps, and correspondingly, the second interconnection structure in the bonding layer is the conductive bumps.

In the present embodiment, the height h of the first chip structure 102 should not be too large. If the height h of the first chip structure 102 is too large, then it is easy to cause an excessive height difference between the first chip structure 102 and the first carrier board 100, so that the difficulty of forming the first interconnection structure 105 on the first carrier board 100 at the side of the first chip structure 102 and on the top of the second functional layer 104 is increased. Therefore, in the present embodiment, the height h of the first chip structure 102 is less than or equal to 50 micrometers.

In the present embodiment, the height h of the first chip structure 102 refers to the sum of the height of the first functional layer 103, the height of the second functional layer 104, and the height of the bonding layer 106.

The first interconnection structure 105 is used to achieve electrical connection with the first functional layer 103 and also to achieve electrical connection with the second functional layer 104.

In some embodiments, through the first interconnection structure 105, the electrical properties of the first functional layer 103 and the second functional layer 104 are both connected to the same side, so that it facilitates subsequent further package integration of the first chip structure 102.

Moreover, the first interconnection structure 105 at the side of the first chip structure 102 is electrically connected with the first functional layer 103 through the first carrier board 100, and the first interconnection structure 105 on the top of the second functional layer 104 is electrically connected with the second functional layer 104, consequently, the power supply circuit of the power layer can be separated from the signal transmission circuit of the signal layer, and the interference of the power supply circuit of the power layer on signals in the signal layer is effectively reduced, so that the overall voltage and power consumption of the package structure are reduced and the efficiency of the package structure is improved.

In the present embodiment, the material of the first interconnection structure 105 includes copper, aluminum, gold, or silver. Copper, aluminum, gold, or silver have excellent electrical conductivity and thermal conductivity. As an example, the material of the first interconnection structure 105 is copper.

In the present embodiment, the height h1 of the first interconnection structure 105 at the side of the first chip structure 102 equals the sum of the height h of the first chip structure 102 and the height h2 of the first interconnection structure 105 at the top of the second functional layer 104, thus it is easy to make an end of each first interconnection structure 105 facing away from the first carrier board 100 flush with each other, correspondingly, the flatness of the top surface of the package module formed by the first carrier board 100, the first chip structure 102, and the first interconnection structure 105 is improved, thus facilitating subsequent package integration of the package module.

In the present embodiment, the package structure further includes: a second carrier board 107 located at a side of the first interconnection structure 105 facing away from the first carrier board 100, and the second carrier board 107 has a second line 108 and a third line 109, and the second line 108 is electrically connected with the first interconnection structure 105 electrically connected with the power layer, and the third line 109 is electrically connected with the first interconnection structure 105 electrically connected with the signal layer.

The second carrier board 107 is used to achieve electrical connections between the signal layer and other chip structures, and also used to apply an external voltage to the power layer.

As an example, the second carrier board 107 includes a resin substrate, a ceramic substrate, a glass substrate, a silicon substrate, or a printed circuit board.

It should be noted that the first interconnection structure 105 electrically connected with the power layer is electrically connected with the second carrier board 107 through the second line 108, thereby achieving electrical connection between the power layer and the second carrier board 107, and external circuits, in turn, can independently apply external voltage to the power layer through the second carrier board 107; the first interconnection structure 105 electrically connected with the signal layer is connected with the second carrier board 107 through a third line 109, thereby achieving electrical connection between the signal layer and the second carrier board 107, so that the signal layer can transmit signals with other chip structures through the second carrier board 107.

It should also be noted that by arranging the first line 101 in the first carrier board 100 and arranging the second line 108 and the third line 109 in the second carrier board 107, on the one hand, interference between lines can be reduced, and on the other hand, it is also beneficial to simplify the wiring difficulty, thereby improving the yield of the package structure.

In other embodiments, the first interconnection structure may also not be arranged on the second carrier board, and correspondingly, the package structure may also not include the second carrier board.

In the present embodiment, the package structure further includes: a second chip structure 110 located on the second carrier board 107 at the side of the first carrier board 100 and electrically connected with the signal layer through the third line 109 of the second carrier board 107.

In some embodiments, the second chip structure 110 achieves signal transmission with the signal layer in the first chip structure 102 through the third line 109 of the second carrier board 107.

In the present embodiment, the first functional layer 103 is a power layer, and the second functional layer 104 is a signal layer, consequently, the first interconnection structure 105 at the side of the first chip structure 102 is located at a side of the first chip structure 102 away from the second chip structure 110, which is conducive to shortening the transmission path between the signal layer and the second chip structure 110, thereby improving the integrity of the signal during transmission; meanwhile, it is also conducive to reducing the interference of power supply circuit with signal transmission circuit. In other embodiments, the first interconnection structure at the side of the first chip structure may also be located at other positions.

In the present embodiment, the surface of the first carrier board 100 facing away from the second carrier board 107 is flush with the surface of the second chip structure 110 facing away from the second carrier board 107, i.e., the surface of the first carrier board 100 facing away from the second carrier board 107 and the surface of the second chip structure 110 facing away from the second carrier board 107 form a flat surface, which is conducive to reducing mechanical stress concentration and correspondingly reducing the probability of cracking in the package structure during using process.

In some embodiments, by adjusting the thickness of the first carrier board 100, the surface of the first carrier board 100 facing away from the second carrier board 107 is made to be flush with the surface of the second chip structure 110 facing away from the second carrier board 107.

In other embodiments, the thickness of the first carrier board and the thickness of the bonding layer can also be adjusted, such that the surface of the first carrier board facing away from the second carrier board is flush with the surface of the second chip structure facing away from the second carrier board.

In the present embodiment, the second chip structure 110 includes a memory chip structure 111.

In some embodiments, the second chip structure 110 is formed by stacked memory chip structures 111, and the number of the memory chip structures 111 can be set according to actual requirements, and adjacent memory chip structures 111 are connected through a fourth conductive connection piece 112. As an example, the fourth conductive connection piece 112 is conductive bumps. As an example, the material of the fourth conductive connection piece 112 includes one or more of tin, tin-silver, tin-lead, tin-silver-copper, tin-silver-zinc, tin-zinc, tin-bismuth-indium, tin-indium, tin-gold, tin-copper, tin-zinc-indium, and tin-silver-antimony.

As an example, the memory chip structure 111 includes volatile memory chips (e.g., dynamic random access memory or static random access memory) or non-volatile memory chips (e.g., flash memory, phase-change static random access memory, magnetoresistance static random access memory, ferroelectric static random access memory, or resistive static random access memory).

In other embodiments, the memory chip structure may also be connected through hybrid bonding.

In the present embodiment, the package structure further includes: a molding layer 113 located on the first carrier board 100, and the molding layer 113 covers the first chip structure 102 and the first interconnection structure 105, and the molding layer 113 exposes an end of the first interconnection structure 105 facing away from the first carrier board 100.

It should be noted that through the molding layer 113, the stability of the first chip structure 102 and the first interconnection structure 105 on the first carrier board 100 can be improved, and the rigidity between the three of the first carrier board 100, the first chip structure 102, and the first interconnection structure 105 can also be enhanced, and correspondingly, in the process of bonding the first interconnection structure 105 on the second carrier board 107, the reliability of the package is improved.

In other embodiments, the molding layer may also mold the second chip structure in it. In other embodiments, the package structure may also not include the molding layer.

In the present embodiment, the material of the molding layer 113 includes epoxy resin, polyimide resin, benzocyclobutene resin, or polybenzoxazole resin.

It should be noted that the height h1 of the first interconnection structure 105 at the side of the first chip structure 102 equals the sum of the height h of the first chip structure 102 and the height h2 of the first interconnection structure 105 at the top of the second functional layer 104, which facilitates the exposure of an end of each first interconnection structure 105 facing away from the first carrier board 100 by the molding layer 113.

In the present embodiment, the package structure further includes: a first conductive connection piece 114 located between the second carrier board 107 and the first interconnection structure 105 at the side of the first chip structure 102, and electrically connecting the second carrier board 107 and the first interconnection structure 105 at the side of the first chip structure 102; a second conductive connection piece 115 located between the second carrier board 107 and the first interconnection structure 105 at the top of the second functional layer 104, and electrically connecting the second carrier board 107 and the first interconnection structure 105 at the top of the second functional layer 104; and a third conductive connection piece 116 located between the second chip structure 110 and the second carrier board 107, and electrically connecting the second chip structure 110 and the second carrier board 107.

Any one of the first conductive connection piece 114, the second conductive connection piece 115, and the third conductive connection piece 116 may be a structure such as a conductive bump or a conductive pillar, etc., and the material of the conductive bump includes one or more of tin, tin-silver, tin-lead, tin-silver-copper, tin-silver-zinc, tin-zinc, tin-bismuth-indium, tin-indium, tin-gold, tin-copper, tin-zinc-indium, and tin-silver-antimony, and the material of the conductive pillar includes one or more of copper, silver, nickel, gold, and aluminum.

As an example, the first conductive connection piece 114, the second conductive connection piece 115, and the third conductive connection piece 116 are all conductive bumps.

As an example, the materials of the first conductive connection piece 114, the second conductive connection piece 115, and the third conductive connection piece 116 are the same, for example, the materials of the first conductive connection piece 114, the second conductive connection piece 115, and the third conductive connection piece 116 all are tin.

In other embodiments, the materials of the first conductive connection piece, the second conductive connection piece, and the third conductive connection piece may also be different.

In the present embodiment, the semiconductor structure further includes: a fifth conductive connection piece 117 located on the second carrier board 107 and located at a side of the second carrier board 107 facing away from the first chip structure 102.

In some embodiments, the fifth conductive connection piece 117 facilitates subsequent bonding the second carrier board 107 on other carrier boards (e.g., printed circuit boards).

In some embodiments, the fifth conductive connection piece 117 may be a structure such as a conductive bump or a conductive pillar, etc., and the material of the conductive bump includes one or more of tin, tin-silver, tin-lead, tin-silver-copper, tin-silver-zinc, tin-zinc, tin-bismuth-indium, tin-indium, tin-gold, tin-copper, tin-zinc-indium, and tin-silver-antimony, and the material of the conductive pillar includes one or more of copper, silver, nickel, gold, and aluminum. As an example, the fifth conductive connection piece 117 is a conductive bump.

FIG. 2 is a structural schematic diagram of a second embodiment of the package structure of the present disclosure.

The similarities between the present embodiment and the aforementioned embodiment will not be repeated herein. The differences between the present embodiment and the aforementioned embodiment lie in: the first functional layer 203 is a signal layer, and the second functional layer 204 is a power layer.

In some embodiments, an external voltage supplies power to the signal layer through the power layer (i.e., the second functional layer 204), and the signal layer (i.e., the first functional layer 203) is used to achieve signal transmission between different chip structures.

It should be noted that when the first functional layer 203 includes a first conductive layer 220 and a first lead 221 electrically connected with the first conductive layer 220, the first lead 221 is located at a side of the first functional layer 203 facing the first carrier board 200, and another end of the first lead 221 is electrically connected with the first line 201; the second functional layer 204 includes a second conductive layer 222 and a second lead 223 electrically connected with the second conductive layer 222, and the second lead 223 is located at a side of the second functional layer 204 facing away from the first carrier board 200, and another end of the second lead 223 is electrically connected with the first interconnection structure 205 on the top of the power layer.

It should also be noted that the first functional layer 203 is a signal layer, and the second functional layer 204 is a power layer, correspondingly, the power layer is located at a side of the signal layer facing away from the first carrier board 200, which means that when the first chip structure 202 is bonded on the second carrier board 207, the power layer is closer to the second carrier board 207, which is conducive to shortening the power supply circuit and improving power supply efficiency.

Furthermore, when the first functional layer 203 is a signal layer, the first interconnection structure 205 at the side of the first chip structure 202 is located at a side of the first chip structure 202 facing the second chip structure 210, which is conducive to shortening the transmission path between the signal layer and the second chip structure 210, thereby improving the integrity of the signal during transmission; meanwhile, it is also conducive to reducing the interference of power supply circuit with signal transmission circuit. In other embodiments, the first interconnection structure at the side of the first chip structure may also be located at other positions.

Correspondingly, the embodiments of the present disclosure also provide a package method. FIGS. 3 to 9 are structural schematic diagrams corresponding to each step in a first embodiment of the package method of the present disclosure.

Referring to FIG. 3, a first carrier board 500 is provided, and the first carrier board 500 includes a first line 501.

As an example, the first carrier board 500 is a silicon carrier board. For relevant descriptions of the first carrier board 500, reference may be made to the aforementioned embodiments and it will not be repeated herein.

In the present embodiment, the first line 501 is a redistribution layer used to electrically connect the first functional layer and the first interconnection structure on the first carrier board 500. In other embodiments, the first line may also be other types of wiring structures, for example, the first line may include an interconnection layer and interconnection through-hole structures electrically connected with the interconnection layer.

Referring again to FIG. 3, a first chip structure 502 is arranged on the first carrier board 500, and the first chip structure 502 includes a first functional layer 503 located on the first carrier board 500 and a second functional layer 504 bonded on the first functional layer 503, and the first functional layer 503 is electrically connected with the first carrier board 500, and the second functional layer 504 is electrically connected with the first functional layer 503, and one of the first functional layer 503 and the second functional layer 504 is a power layer, and the other is a signal layer.

For the type of the first chip structure 502, reference may be made to corresponding descriptions in other embodiments, and it will not be repeated herein.

In the present embodiment, the method for arranging the first chip structure 502 on the first carrier board 500 includes: using a hybrid bonding process.

It should be noted that the first carrier board 500 is provided with a first line 501 and a first dielectric layer (not shown in the figure) exposing the area to be connected of the first line 501, and the first functional layer 503 includes a first lead 521 and a second dielectric layer (not labeled) exposing the area to be connected of the first lead 521, therefore, the first chip structure 502 can be bonded on the first carrier board 500 through the hybrid bonding process.

One of the first functional layer 503 and the second functional layer 504 serves as a power layer, and the other serves as a signal layer. In the present embodiment, the first functional layer 503 is the power layer, and the second functional layer 504 is the signal layer, so that when the first chip structure 502 is subsequently bonded on the second carrier board, it facilitates the electrical connection between the signal layer and other chip structures through the second carrier board, meanwhile, the transmission path between the signal layer and the second carrier board is also shortened, and interference between lines is reduced.

In some embodiments, an external voltage supplies power to the signal layer through the power layer (i.e., the first functional layer 503), and the signal layer (i.e., the second functional layer 504) is used to achieve signal transmission between different chip structures.

It should be noted that when the first functional layer 503 includes a first conductive layer 520 and a first lead 521 electrically connected with the first conductive layer 520, the first lead 521 is located at a side of the first functional layer 503 facing the first carrier board 500, and another end of the first lead 521 is electrically connected with the first line 501; the second functional layer 504 includes a second conductive layer 522 and a second lead 523 electrically connected with the second conductive layer 522, and the second lead 523 is located at a side of the second functional layer 504 facing away from the first carrier board 500, and another end of the second lead 523 is electrically connected with the first interconnection structure on the top of the second functional layer 504.

In the present embodiment, the second functional layer 504 is bonded on the first functional layer 503, i.e., the first functional layer 503 and the second functional layer 504 can be fabricated respectively, so that the process compatibility between the two is improved, meanwhile, the process flow can also be simplified and the complexity of process is reduced.

In the present embodiment, in the step of arranging the first chip structure 502 on the first carrier board 500, the first chip structure 502 further includes: a bonding layer 506 located between the first functional layer 503 and the second functional layer 504 and electrically connecting the first functional layer 503 and the second functional layer 504.

In some embodiments, the bonding layer 506 includes an insulating layer 524 and a second interconnection structure 525 located within the insulating layer 524, and the first functional layer 503 and the second functional layer 504 are electrically connected through the second interconnection structure 525.

It should be noted that, the fact that the bonding layer 506 is a hybrid bonding layer facilitates increasing the number of second interconnection structures 525 and also facilitates reducing the thickness of the package structure.

As an example, the second interconnection structure 525 is a conductive pillar passing through the insulating layer 524. In other embodiments, according to actual process requirements, the second interconnection structure may also include an interconnection layer and interconnection through-hole structures electrically connecting the interconnection layer. In other embodiments, the bonding layer may also be formed by conductive bumps, and correspondingly, the second interconnection structure in the bonding layer is the conductive bumps.

In the present embodiment, the height H of the first chip structure 502 is less than or equal to 50 micrometers.

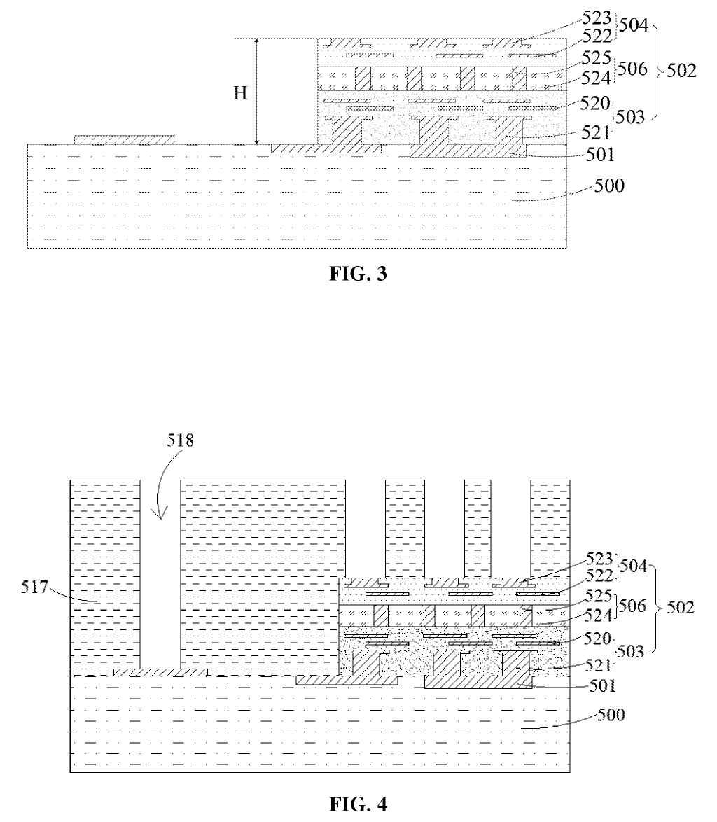

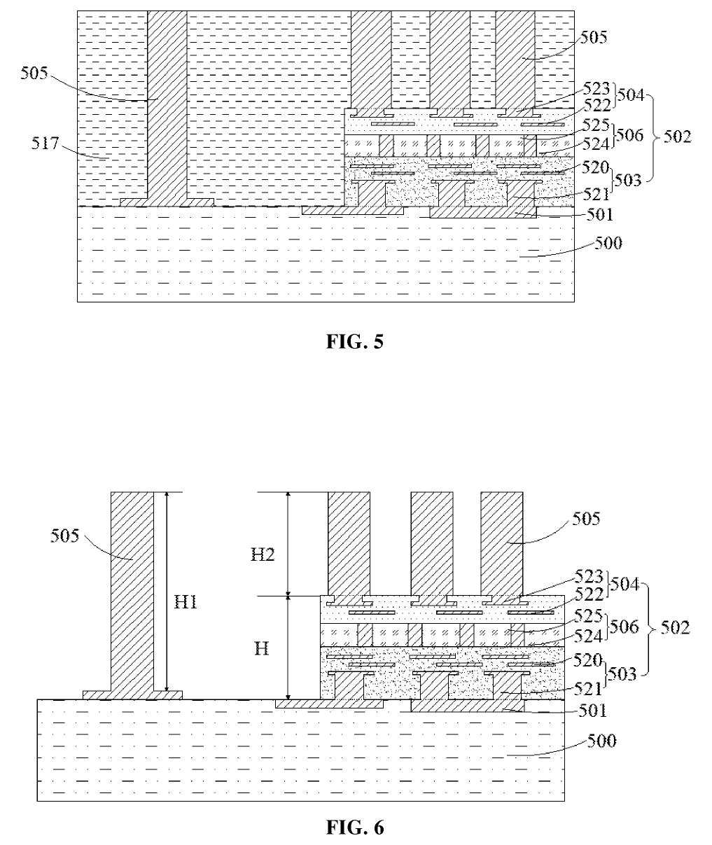

Referring to FIGS. 4 to 6, a first interconnection structure 505 is formed on the first carrier board 500 at the side of the first chip structure 502, and on the top of the second functional layer 504 facing away from the first functional layer 503 (as shown in FIGS. 5 and 6), the first interconnection structure 505 at the side of the first chip structure 502 is electrically connected with the first functional layer 503 through the first line 501, and the first interconnection structure 505 on the top of the second functional layer 504 is electrically connected with the second functional layer 504.

The first interconnection structure 505 is used to achieve electrical connection with the first functional layer 503 and also used to achieve electrical connection with the second functional layer 504. In some embodiments, through the first interconnection structure 505, the electrical properties of the first functional layer 503 and the second functional layer 504 are both connected to the same side, so that it facilitates subsequent further package integration of the first chip structure 502. Moreover, the first interconnection structure 505 at the side of the first chip structure 502 is electrically connected with the first functional layer 503 through the first carrier board 500, and the first interconnection structure 505 on the top of the second functional layer 504 is electrically connected with the second functional layer 504, consequently, the power supply circuit of the power layer can be separated from the signal transmission circuit of the signal layer, thus the interference of the power supply circuit of the power layer on signals in the signal layer can be effectively reduced, so that the overall voltage and power consumption of the package structure are reduced and the efficiency of the package structure is improved.

In the present embodiment, the material of the first interconnection structure 505 includes copper, aluminum, gold, or silver. As an example, the material of the first interconnection structure 505 is copper.

Referring to FIG. 6, the height H1 of the first interconnection structure 505 at the side of the first chip structure 502 equals the sum of the height H of the first chip structure 502 and the height H2 of the first interconnection structure 505 at the top of the second functional layer 504, thus it is easy to make an end of each first interconnection structure 505 facing away from the first carrier board 500 is flush with each other, correspondingly, the flatness of the top surface of the package module formed by the first carrier board 500, the first chip structure 502, and the first interconnection structure 505 is improved, thereby facilitating subsequent package integration of the package module.

In some embodiments, the step of respectively forming the first interconnection structure 505 on the first carrier board 500 at the side of the first chip structure 502 and on the top of the second functional layer 504 facing away from the first functional layer 503 includes: referring to FIG. 4, a sacrificial layer 517 is formed on the first carrier board, and the sacrificial layer 517 also covers the top of the first chip structure 502; referring again to FIG. 4, an opening 518 is formed in the sacrificial layer 517, and the opening 518 passes through the sacrificial layer 517 at the side of the first chip structure 502 and the sacrificial layer 517 on the top of the second functional layer 504, respectively; referring to FIG. 5, the first interconnection structure 505 is formed within the opening 518; referring to FIG. 6, after forming the first interconnection structure 505, the process further includes: removing the sacrificial layer 517.

The sacrificial layer 517 is used as a temporary support structure to facilitate the formation of the first interconnection structure 505. The opening 518 is used to provide spatial position for the first interconnection structure 505.

It should be noted that by forming the opening 518 in the sacrificial layer 517 and then forming the first interconnection structure 505 in the opening 518, it is conductive to reducing the difficulty of forming the first interconnection structure 505.

It should also be noted that after forming the first interconnection structure 505, the sacrificial layer 517 is removed to prepare for subsequent formation of the molding layer.

In the present embodiment, in the step of forming the sacrificial layer 517 on the first carrier board 500, the sacrificial layer 517 includes photoresist. The photoresist can be directly patterned through photolithography process, which can reduce the complexity of forming the opening 518 and facilitate precise control of the dimensions of the opening 518; meanwhile, the photoresist is easy to be removed, thereby reducing process complexity and improving production efficiency. In other embodiments, for the sacrificial layer, other materials may also be selected that can serve as temporary support structures and are easy to be removed.

In other embodiments, the step of respectively forming a first interconnection structure on the first carrier board at the side of the first chip structure and on the top of the second functional layer facing away from the first functional layer may further include: providing a first interconnection structure; forming solder balls at the end of the first interconnection structure; and pressure welding the first interconnection structure onto the first carrier board at the side of the first chip structure and onto the top of the second functional layer facing away from the first functional layer through the solder balls, which is conductive to reducing the complexity of the process and thus reducing production costs.

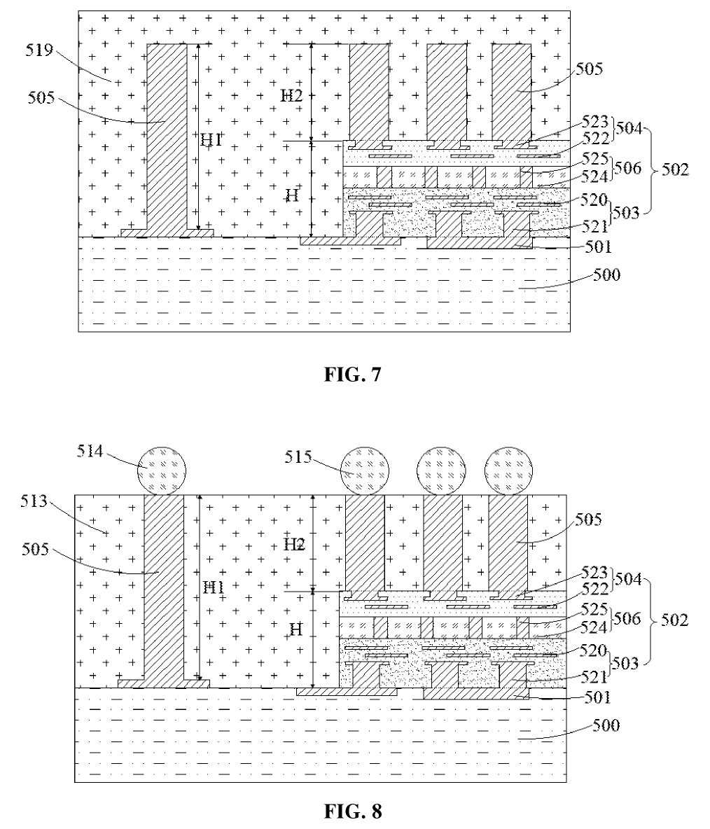

Referring to FIGS. 7 to 8, before bonding the first interconnection structure 505 on the second carrier board, the package method further includes: forming a molding layer 513 on the first carrier board 500 (as shown in FIG. 8), the molding layer 513 covers the first chip structure 502 and the first interconnection structure 505, and the molding layer 513 exposes an end of the first interconnection structure 505 facing away from the first carrier board 500.

It should be noted that through the molding layer 513, the stability of the first chip structure 502 and the first interconnection structure 505 on the first carrier board 500 can be improved, and the rigidity between the three of the first carrier board 500, the first chip structure 502, and the first interconnection structure 505 can also be enhanced, correspondingly, in the process of bonding the first interconnection structure 505 on the second carrier board, the reliability of the package structure is improved.

In other embodiments, the molding layer can also mold the second chip structure inside. In other embodiments, the package structure may not include a molding layer.

In the present embodiment, the material of the molding layer 513 includes epoxy resin, polyimide resin, benzocyclobutene resin, or polybenzoxazole resin.

It should be noted that the height H1 of the first interconnection structure 505 at the side of the first chip structure 502 equals the sum of the height H of the first chip structure 502 and the height H2 of the first interconnection structure 505 at the top of the second functional layer 504, which facilitates the exposure of an end of each first interconnection structure 505 facing away from the first carrier board 500 by the molding layer 513.

In some embodiments, the step of forming the molding layer 513 on the first carrier board 500 includes: referring to FIG. 7, a molding material layer 519 is formed on the first carrier board 500, and the molding material layer 519 covers the first chip structure 502 and the first interconnection structure 505; referring to FIG. 8, the molding material layer 519 higher than the end of the first interconnection structure 505 facing away from the first carrier board 500 is removed, and the remaining molding material layer 519 serves as the molding layer 513.

The molding material layer 519 is used to form the molding layer 513.

It should be noted that by forming the molding material layer 519 on the first carrier board 500 and then removing the molding material layer 519 higher than the end of the first interconnection structure 505 facing away from the first carrier board 500, it is conductive to improving the thickness uniformity of the molding layer 513.

It should also be noted that the molding material layer 519 higher than the end of the first interconnection structure 505 facing away from the first carrier board 500 is removed, and an end of the first interconnection structure 505 facing away from the first carrier board 500 is exposed to facilitate subsequent electrical connection between the end of the first interconnection structure 505 facing away from the first carrier board 500 and the second carrier board.

In the present embodiment, the process for removing the molding material layer 519 higher than the end of the first interconnection structure 505 facing away from the first carrier board 500 includes a grinding process. The grinding process can accurately control the thickness of the removed molding material layer 519, which is conductive to exposing the top of the first interconnection structure 505 and avoiding excessive removal of the molding material layer 519; furthermore, it is also conductive to improving the flatness of the surface formed by the first interconnection structure 505 and the molding layer 513, so as to prepare for subsequent processes.

Referring again to FIG. 8, after forming the molding layer 513 on the first carrier board 500 and before bonding the first interconnection structure 505 on the second carrier board, the process further includes: forming a first conductive connection piece 514 on the top of the first interconnection structure 505 at the side of the first chip structure 502, and forming a second conductive connection piece 515 on the top of the first interconnection structure 505 at the top of the second functional layer 504.

Any one of the first conductive connection piece 514 and the second conductive connection piece 515 may be a structure such as a conductive bump or a conductive pillar, etc., and the material of the conductive bump includes one or more of tin, tin-silver, tin-lead, tin-silver-copper, tin-silver-zinc, tin-zinc, tin-bismuth-indium, tin-indium, tin-gold, tin-copper, tin-zinc-indium, and tin-silver-antimony. As an example, both the first conductive connection piece 514 and the second conductive connection piece 515 are conductive bumps.

As an example, the materials of the first conductive connection piece 514 and the second conductive connection piece 515 are the same, for example, the materials of the first conductive connection piece 514 and the second conductive connection piece 515 both are tin. In other embodiments, the materials of the first conductive connection piece and the second conductive connection piece may also be different.

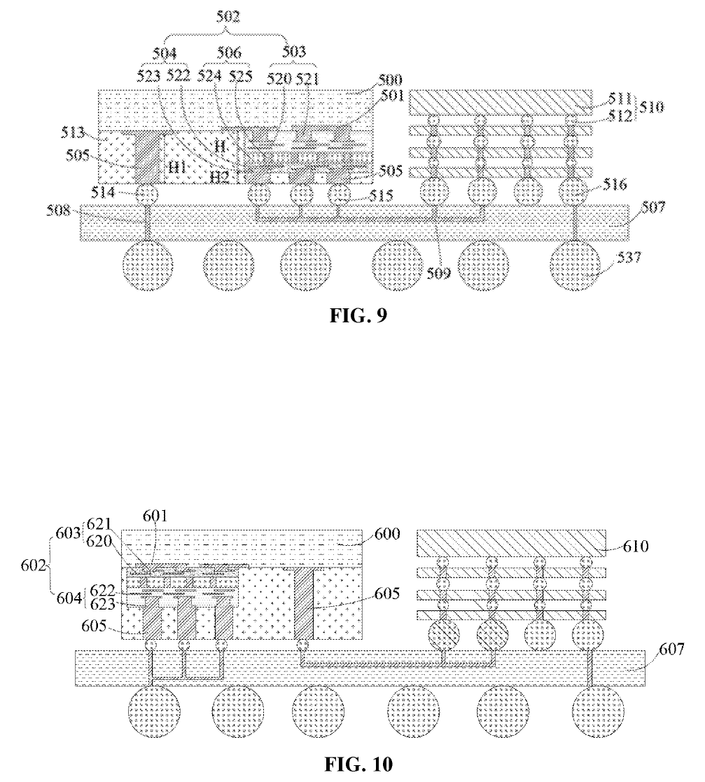

Referring to FIG. 9, the package method further includes: providing a second carrier board 507, the second carrier board 507 has a second line 508 and a third line 509; after forming the first interconnection structure 505 on the first carrier board 500 at the side of the first chip structure 502 and on the top of the second functional layer 504 facing away from the first functional layer 503, bonding the first interconnection structure 505 on the second carrier board 507, the first interconnection structure 505 electrically connecting with the power layer is electrically connected with the second line 508; and the first interconnection structure 505 electrically connecting with the signal layer is electrically connected with the third line 509; bonding the second chip structure 510 on the second carrier board 507, the second chip structure 510 is located at the side of the first carrier board 500, and the second chip structure 510 is electrically connected with the signal layer through the third line 509 of the second carrier board 507.

The second carrier board 507 is used to achieve electrical connection between the signal layer and other chip structures, and also used to apply an external voltage to the power layer. For relevant descriptions of the second carrier board 507, reference may be made to the aforementioned embodiments and it will not be repeated herein.

It should be noted that the first interconnection structure 505 electrically connected with the power layer is electrically connected with the second carrier board 507 through the second line 108, thereby achieving electrical connection between the power layer and the second carrier board 507, so that external circuits can independently apply external voltage to the power layer through the second carrier board 507; the first interconnection structure 505 electrically connected with the signal layer is connected with the second carrier board 507 through a third line 509, thereby achieving electrical connection between the signal layer and the second carrier board 507, so that the signal layer can transmit signals with other chip structures through the second carrier board 507.

It should also be noted that by arranging the first line 501 in the first carrier board 500 and arranging the second line 108 and the third line 509 in the second carrier board 507, on the one hand, interference between lines can be reduced, and on the other hand, it is also beneficial to simplify the wiring difficulty, thereby improving the yield of the package structure.

In other embodiments, the first interconnection structure may also not be arranged on the second carrier board, and correspondingly, the package structure may also not include the second carrier board.

In some embodiments, the second chip structure 510 achieves signal transmission with the signal layer in the first chip structure 502 through the third line 509 of the second carrier board 507.

In the present embodiment, the first functional layer 503 is a power layer, and the second functional layer 504 is a signal layer, consequently, the first interconnection structure 505 at the side of the first chip structure 502 is located at a side of the first chip structure 502 away from the second chip structure 510, which is conducive to shortening the transmission path between the signal layer and the second chip structure 110, thereby improving the integrity of the signal during transmission; meanwhile, it is also conducive to reducing the interference of power supply circuit with signal transmission circuit.

In the present embodiment, by adjusting the thickness of the first carrier board 500, the surface of the first carrier board 500 facing away from the second carrier board 507 is made to be flush with the surface of the second chip structure 510 facing away from the second carrier board 507. In other embodiments, the thickness of the first carrier board and the thickness of the bonding layer can also be adjusted, such that the surface of the first carrier board facing away from the second carrier board is flush with the surface of the second chip structure facing away from the second carrier board.

In the present embodiment, the second chip structure 510 includes a memory chip structure 511. In some embodiments, the second chip structure 510 is formed by stacked memory chip structures 511, and the number of the memory chip structures 511 can be set according to actual requirements, and adjacent memory chip structures 511 are connected through a fourth conductive connection piece 512. In other embodiments, the memory chip structures may also be connected by means of hybrid bonding.

For the material type of the fourth conductive connection piece 512, reference may be made to corresponding descriptions of other embodiments and it will not be repeated herein.

As an example, the memory chip structure 511 includes volatile memory chips or non-volatile memory chips.

Referring to FIG. 9, the step of bonding the first interconnection structure 505 on the second carrier board 507 includes: through the first conductive connection piece 514, the first interconnection structure 505 at the side of the first chip structure 502 is bonded on the second carrier board 507 and is electrically connected with the second carrier board 507; through the second conductive connection piece 515, the first interconnection structure 505 which is electrically connected with the top of the second functional layer 504, is bonded on the second carrier board 507 and is electrically connected with the second carrier board 507.

It should be noted that in the present embodiment, before bonding the first interconnection structure 505 on the second carrier board 507, the first conductive connection piece 514 and the second conductive connection piece 515 are first formed on the top of the first interconnection structure 505, respectively. In other embodiments, before bonding the first interconnection structure on the second carrier board, the first conductive connection piece and the second conductive connection piece may also be first formed on the second carrier board.

Referring to FIG. 9, the step of bonding the second chip structure 510 on the second carrier board 507 includes: through the third conductive connection piece 516, the second chip structure 510 is bonded on the second carrier board 507 and is electrically connected with the second carrier board 507.

The material of the third conductive connection piece 516 includes one or more of tin, tin-silver, tin-lead, tin-silver-copper, tin-silver-zinc, tin-zinc, tin-bismuth-indium, tin-indium, tin-gold, tin-copper, tin-zinc-indium, and tin-silver-antimony. As an example, the materials of the third conductive connection piece 516, the first conductive connection piece 514, and the second conductive connection piece 515 are the same, for example, the materials of the third conductive connection piece 516, the first conductive connection piece 514, and the second conductive connection piece 515 all are tin.

In other embodiments, the materials of the first conductive connection piece, the second conductive connection piece, and the third conductive connection may also be different.

It should be noted that before bonding the second chip structure 510 on the second carrier board 507, the third conductive connection piece 516 may be first formed on the second chip structure 510, and the third conductive connection piece 516 may also be first formed on the second carrier board 507.

Referring to FIG. 9, the package method further includes: forming a fifth conductive connection piece 537 at a side of the second carrier board 507 facing away from the first chip structure 502. For a detailed description of the fifth conductive connection piece 537, reference may be made to the relevant content of the aforementioned embodiments, and it will not be repeated herein.

It should be noted that the package structure of the aforementioned first embodiment may be obtained using the package method of the first embodiment and may also be obtained using other package methods. For a detailed description of the package method of the first embodiment, reference may be made to the relevant content of the package structure of the first embodiment.

FIG. 10 is a structural schematic diagram corresponding to the steps in a second embodiment of the package method of the present disclosure.

The similarities between the present embodiment and the aforementioned embodiments are not repeated herein. The difference between the present embodiment and the aforementioned embodiments lies in: in the step of arranging a first chip structure 602 on a first carrier board 600, a first functional layer 603 is a signal layer, and a second functional layer 604 is a power layer.

In some embodiments, an external voltage supplies power to the signal layer through the power layer (i.e., the second functional layer 604), and the signal layer (i.e., the first functional layer 603) is used to achieve signal transmission between different chip structures.

It should be noted that the first functional layer 603 includes a first conductive layer 620 and a first lead 621 electrically connected with the first conductive layer 620, and the first lead 621 is located at a side of the first functional layer 603 facing the first carrier board 600, and another end of the first lead 621 is electrically connected with a first line 601; the second functional layer 604 includes a second conductive layer 622 and a second lead 623 electrically connected with the second conductive layer 622, and the second lead 623 is located at a side of the second functional layer 604 facing away from the first carrier board 600, and another end of the second lead 623 is electrically connected with a first interconnection structure 605 on the top of the power layer.

It should be noted that the first functional layer 603 is a signal layer, and the second functional layer 604 is a power layer, correspondingly, the power layer is located at a side of the signal layer facing away from the first carrier board 600, which means that when the first chip structure 602 is bonded on the second carrier board 607, the power layer is closer to the second carrier board 607, which is conducive to shortening the power supply circuit and improving power supply efficiency.

It should also be noted that when the first functional layer 603 is a signal layer, the first interconnection structure 605 at the side of the first chip structure 602 is located at a side of the first chip structure 602 facing the second chip structure 610, which is conducive to shortening the transmission path between the signal layer and the second chip structure 610, thereby improving the integrity of the signal during transmission.

It should be noted that the package structure of the aforementioned second embodiment may be obtained using the package method of the second embodiment and may also be obtained using other package methods. For a detailed description of the package method of the second embodiment, reference may be made to the relevant content of the package structure of the second embodiment.

Although the present disclosure is disclosed as above, the present disclosure is not limited thereto. Any skilled in the art may also make various changes and modifications without departing from the spirit and scope of the present disclosure, therefore the scope of protection of the present disclosure shall be subject to the scope defined by the claims.

What is claimed is:

1. A package structure, comprising:
a first carrier board comprising a first line;
a first chip structure comprising: a first functional layer located on the first carrier board and a second functional layer bonded on the first functional layer, wherein the first functional layer is electrically connected to the first carrier board, the second functional layer is electrically connected to the first functional layer, and one of the first functional layer and the second functional layer is a power layer and another one of the first functional layer and the second functional layer is a signal layer; and
a first interconnection structure located on the first carrier board at a side of the first chip structure and on a top of the second functional layer facing away from the first functional layer, respectively, wherein the first interconnection structure at the side of the first chip structure is electrically connected to the first functional layer through the first line, and the first interconnection structure on the top of the second functional layer is electrically connected to the second functional layer.

2. The package structure according to claim 1, wherein
the first chip structure further comprises a bonding layer located between the first functional layer and the second functional layer; and
the bonding layer comprises a second interconnection structure electrically connected to the first functional layer and the second functional layer.

3. The package structure according to claim 1, further comprising:
a second carrier board located at a side of the first interconnection structure facing away from the first carrier board, wherein the second carrier board comprises a second line and a third line, the second line is electrically connected to the first interconnection structure electrically connected to the power layer, and the third line is electrically connected to the first interconnection structure electrically connected to the signal layer; and
a second chip structure located on the second carrier board at a side of the first carrier board and electrically connected to the signal layer through the third line of the second carrier board.

4. The package structure according to claim 1, wherein the first functional layer is a power layer, and the second functional layer is a signal layer.

5. The package structure according to claim 1, further comprising:
a molding layer located on the first carrier board, wherein the molding layer covers the first chip structure and the first interconnection structure and exposes an end of the first interconnection structure facing away from the first carrier board.

6. The package structure according to claim 3, wherein
when the second functional layer is a signal layer, the first interconnection structure at the side of the first chip structure is located at a side of the first chip structure away from the second chip structure; or
when the first functional layer is a signal layer, the first interconnection structure at the side of the first chip structure is located at a side of the first chip structure facing the second chip structure.

7. The package structure according to claim 3, further comprising:
a first conductive connection piece located between the second carrier board and the first interconnection structure at the side of the first chip structure, and electrically connecting the second carrier board and the first interconnection structure at the side of the first chip structure;
a second conductive connection piece located between the second carrier board and the first interconnection structure on the top of the second functional layer, and electrically connecting the second carrier board and the first interconnection structure on the top of the second functional layer; and
a third conductive connection piece located between the second chip structure and the second carrier board, and electrically connecting the second chip structure and the second carrier board.

8. The package structure according to claim 3, wherein the second chip structure comprises a memory chip structure.

9. The package structure according to claim 3, wherein a surface of the first carrier board facing away from the second carrier board is flush with a surface of the second chip structure facing away from the second carrier board.

10. The package structure according to claim 1, wherein a material of the first interconnection structure comprises copper, aluminum, gold, or silver.

11. The package structure according to claim 1, wherein a height of the first chip structure is less than or equal to 50 micrometers.

12. The package structure according to claim 1, wherein a height of the first interconnection structure at the side of the first chip structure equals a sum of a height of the first chip structure and a height of the first interconnection structure on the top of the second functional layer.

13. A package method, comprising:
providing a first carrier board comprising a first line;
arranging a first chip structure on the first carrier board, wherein the first chip structure comprises a first functional layer located on the first carrier board and a second functional layer bonded on the first functional layer, the first functional layer is electrically connected to the first carrier board, the second functional layer is electrically connected to the first functional layer, and one of the first functional layer and the second functional layer is a power layer and another one of the first functional layer and the second functional layer is a signal layer; and
forming a first interconnection structure on the first carrier board at a side of the first chip structure and on a top of the second functional layer facing away from the first functional layer, respectively, wherein the first interconnection structure at the side of the first chip structure is electrically connected to the first functional layer through the first line, and the first interconnection structure on the top of the second functional layer is electrically connected to the second functional layer.

14. The package method according to claim 13, wherein arranging the first chip structure on the first carrier board comprises: bonding the first functional layer on the first carrier board through a hybrid bonding process.

15. The package method according to claim 13, wherein the first chip structure further comprises a bonding layer located between the first functional layer and the second functional layer, the bonding layer comprising a second interconnection structure electrically connected to the first functional layer and the second functional layer.

16. The package method according to claim 13, wherein forming the first interconnection structure respectively on the first carrier board at the side of the first chip structure and on the top of the second functional layer comprises:
forming a sacrificial layer on the first carrier board, the sacrificial layer covering a top of the first chip structure;
forming an opening in the sacrificial layer, the opening passing through the sacrificial layer at the side of the first chip structure and the sacrificial layer on the top of the second functional layer, respectively;
forming the first interconnection structure in the opening; and removing the sacrificial layer after forming the first interconnection structure; or
wherein forming the first interconnection structure respectively on the first carrier board at the side of the first chip structure and on the top of the second functional layer comprises: providing the first interconnection structure;
forming solder balls at an end of the first interconnection structure; and
pressure welding the first interconnection structure onto the first line at the side of the first chip structure and onto the top of the second functional layer through the solder balls.

17. The package method according to claim 13, further comprising:
providing a second carrier board comprising a second line and a third line;
after forming the first interconnection structure, bonding the first interconnection structure to the second carrier board, wherein the first interconnection structure of the power layer is electrically connected to the second line, and the first interconnection structure of the signal layer is electrically connected to the third line; and
bonding a second chip structure on the second carrier board, wherein the second chip structure is located at a side of the first carrier board and is electrically connected to the signal layer through the third line of the second carrier board.

18. The package method according to claim 17, wherein before bonding the first interconnection structure to the second carrier board, the method further comprises: forming a molding layer on the first carrier board, wherein the molding layer covers the first chip structure and the first interconnection structure and exposes an end of the first interconnection structure facing away from the first carrier board.

19. The package method according to claim 18, wherein forming the molding layer on the first carrier board comprises:
forming a molding material layer on the first carrier board, the molding material layer covering the first chip structure and the first interconnection structure; and
removing a portion of the molding material layer higher than the end of the first interconnection structure facing away from the first carrier board, wherein a remaining portion of the molding material layer serves as the molding layer.

20. The package method according to claim 17, wherein
bonding the first interconnection structure to the second carrier board comprises: bonding the first interconnection structure at the side of the first chip structure to the second carrier board through a first conductive connection piece and bonding the first interconnection structure on the top of the second functional layer to the second carrier board through a second conductive connection piece; and
bonding the second chip structure on the second carrier board comprises: bonding the second chip structure to the second carrier board through a third conductive connection piece.
